(19) United States
(12) Patent Application Publication
(10) Pub. No.: US 2014/0084529 A1
(43) Pub. Date: Mar. 27, 2014

(54) WAFER CARRIER WITH POCKET

(71) Applicant: Chae Hon KIM, Yongin-si (KR)

(72) Inventor: Chae Hon KIM, Yongin-si (KR)

(21) Appl. No.: 13/627,609

(22) Filed: Sep. 26, 2012

(51) Int. Cl. H01L 21/673

(52) U.S. Cl. CPC H01L 21/67346
USPC 269/287

(57) ABSTRACT

Exemplary embodiments of the present invention disclose a wafer carrier with a pocket. The wafer carrier is used for supporting a GaN substrate in a chemical vapor deposition apparatus. The wafer carrier includes a carrier lower surface, a carrier upper surface, and a pocket surrounded by the carrier upper surface. The pocket includes a bottom surface, and a rim arranged along an edge of the bottom surface and located under the carrier upper surface. The rim includes a sidewall extending from the bottom surface, and an upper surface on which the GaN substrate is arranged. A height difference between an edge and a center of the bottom surface is 5 μm or less. Since the bottom surface is formed in a relatively flat shape, epitaxial layers may be uniformly grown on the GaN substrate.

### BACKGROUND

1. Field

Exemplary embodiments of the present invention relate to a wafer carrier for a chemical vapor deposition (CVD) apparatus, and more particularly, to a wafer carrier that includes a pocket for accommodating a wafer on the upper surface thereof.

2. Discussion of the Background

In general, a gallium nitride (GaN)-based semiconductor layer is grown on a heterogeneous substrate, such as a sapphire substrate, by using a chemical vapor deposition (CVD) apparatus. A wafer, such as a sapphire substrate, is put on a wafer carrier within a chamber that can heat the wafer to a high temperature. Then, source gases are introduced into the chamber at a temperature of 500 to 1,200° C., and GaN-based epitaxial layers are grown on the substrate. The wafer carrier includes a pocket for accommodating the substrate. A plurality of pockets may be provided on the wafer carrier. Therefore, the same epitaxial layer can be simultaneously grown on a plurality of substrates through a single deposition process.

Meanwhile, since about 16% lattice mismatch exists between the sapphire substrate and the GaN layer, strain is caused between the grown GaN layer and the sapphire substrate. Such strain causes wafer bowing during the growth.

FIG. 1 is a partial cross-sectional view of a conventional wafer carrier 11.

Referring to FIG. 1, the conventional wafer carrier 11 includes a carrier lower surface 11l, a carrier upper surface 11u, and a pocket 17 surrounded by the carrier upper surface 11u. The pocket 17 includes a bottom surface 13 and a rim 15 surrounding the bottom surface 13. An upper surface 15u of the rim 15 is located under the carrier upper surface 11u of the wafer carrier 11. As illustrated in FIG. 1, a wafer W is put on the upper surface 15u of the rim 15. The wafer carrier 11 is disposed above a heater (not illustrated) and is heated by the heater (not illustrated).

Conventionally, as illustrated in FIG. 1, the bottom surface 13 is formed concavely, and a height difference h1 between the center and the edge of the bottom surface 13 is about 10 to 15 μm. Meanwhile, a height h2 of a sidewall 15s of the rim 15, that is, a distance from the edge of the bottom surface 13 to the upper surface 15u of the rim 15, is about 40 to 50 μm. A distance from the upper surface 15u of the rim 15 to the carrier upper surface 11u of the wafer carrier 11, that is, a height h3 of the carrier upper portion surrounding the side surface of the wafer W, is substantially equal to the thickness of the wafer W.

If using the pocket 17 having the above-described shape, the bottom surface of the wafer W does not come into contact with the bottom surface 13 of the pocket 17, even when bowing occurs in the wafer W. This prevents the wafer W from being released from the pocket 17 due to the wafer bowing. In addition, the shape of the pocket 17 makes it possible to evenly transfer heat over the entire area of the wafer W when an active layer, such as InGaN, is grown. That is, the curvature of the bottom surface 13 of the pocket 17 is set to be similar to the curvature of the bowed wafer W. Therefore, the distance between the bottom surface 13 of the pocket 17 and the bottom surface of the wafer W may be almost constantly maintained.

Since the conventional wafer carrier 11 supports a heterogeneous substrate, such as a sapphire substrate, the height h2 of the rim 15 is relatively high, and the curvature (1/R) of the bottom surface 13 of the pocket 17 is set to be relatively large.

However, as the size of the sapphire substrate increases, the bowing of the wafer W caused by strain also increases. Hence, it is difficult to constantly maintain the distance between the wafer W and the bottom surface 13 of the pocket 17. Furthermore, when the GaN layer is grown on the sapphire substrate, the distance between the bottom surface 13 of the pocket 17 and the bottom surface of the wafer W is considerably changed according to the position of the wafer W, before and after the wafer bowing occurs. Accordingly, when using the sapphire substrate, it is difficult to grow an epitaxial layer having a uniform characteristic over the entire area of the wafer.

Recently, technologies using GaN substrates instead of the sapphire substrate have been introduced. However, when light emitting diodes are formed on a GaN substrate by using a conventional wafer carrier having a pocket shape, non-uniform light emitting diodes are formed according to the position of the GaN substrate.

The above information disclosed in this Background section is only for enhancement of understanding of the background of the invention and therefore it may contain information that does not form any part of the prior art nor what the prior art may suggest to a person of ordinary skill in the art.

### SUMMARY OF THE INVENTION

Exemplary embodiments of the present invention provide a wafer carrier suitable for supporting a GaN substrate in a CVD apparatus.

Additional features of the invention will be set forth in the description which follows, and in part will be apparent from the description, or may be learned by practice of the invention.

According to an embodiment of the present invention, there is provided a wafer carrier for supporting a gallium nitride substrate in a chemical vapor deposition apparatus. The wafer carrier includes: a carrier lower surface; a carrier upper surface; and a pocket surrounded by the carrier upper surface. The pocket may include: a bottom surface; and a rim disposed along an edge of the bottom surface and located under the carrier upper surface. The rim may include a sidewall extending from the bottom surface, and an upper surface on which the gallium nitride substrate is put. A height difference between an edge and a center of the bottom surface may be 5 μm or less. The bottom surface may be flat.

A height of the sidewall of the rim may be in a range of 5 to 10 μm.

In the embodiments, the carrier lower surface may be substantially flat.

According to other embodiments of the present invention, the rim may be removed because the GaN substrate may be put on the bottom surface of the pocket.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a partial cross-sectional view schematically illustrating a conventional wafer carrier.

FIG. 2 is a partial cross-sectional view schematically illustrating a wafer carrier according to an embodiment of the present invention.

FIG. 3 is a partial cross-sectional view schematically illustrating a wafer carrier according to another embodiment of the present invention.

FIGS. 4A and 4B are light distribution views illustrating wavelength distributions of light emitting diodes that are formed on a GaN substrate by using the conventional wafer carrier and the wafer carrier of the present invention.

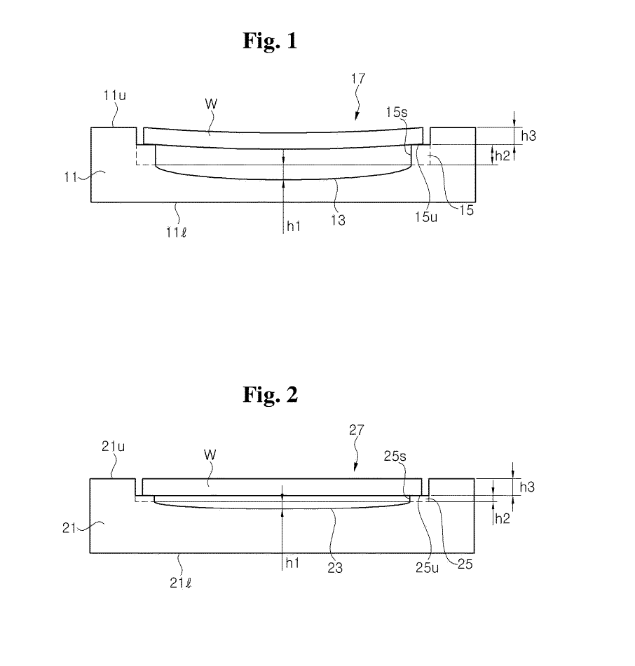

### DETAILED DESCRIPTION OF EXEMPLARY EMBODIMENTS

Exemplary embodiments of the present invention will be described below in detail with reference to the accompanying drawings. These embodiments are provided so that this disclosure will be thorough and complete, and will fully convey the scope of the invention to those skilled in the art. The invention may, however, be embodied in many different forms and should not be construed as being limited to the embodiments set forth herein. In the drawings, the widths, lengths and thicknesses of elements may be exaggerated for clarity. Throughout the drawings and description, like reference numerals will be used to refer to like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

FIG. 2 is a partial cross-sectional view schematically illustrating a wafer carrier 21 according to an embodiment of the present invention.

Referring to FIG. 2, the wafer carrier 21 includes a carrier lower surface 21l, a carrier upper surface 21u, and a pocket 27. The pocket 27 includes a bottom surface 23 and a rim 25.

As illustrated in FIG. 2, it is preferable that the carrier lower surface 21l be substantially flat. Therefore, heat is evenly transferred from a heater (not illustrated), which is disposed under the wafer carrier 21, over the entire area of the carrier lower surface 21l.

In general, the wafer carrier 21 includes a plurality of pockets 27. The carrier upper surface 21u may be an area between the pockets 27. The carrier upper surface 21u is largely flat and surrounds the pockets 27.

The bottom surface 23 of the pocket 27 may have a concave shape, but the present invention is not limited thereto. For example, the bottom surface 23 of the pocket 27 may be substantially flat. It is preferable that a height difference h1 between the edge of the bottom surface 23 and the deepest position, for example, the center of the bottom surface 23, be in a range of 0 to 5 μm. When the height difference h1 exceeds 5 μm, it is difficult to evenly transfer heat to the bottom surface of the substrate W.

The rim 25 surrounds the bottom surface 23 and is disposed along the edge of the bottom surface 23. The rim 25 includes a sidewall 25s extending upward from the edge of the bottom surface 23, and an upper surface 25u on which the substrate W is put. The upper surface 25u of the rim 25 is located under the carrier upper surface 21u.

A height h2 of the sidewall 25s of the rim 25 is 10 μm or less. In particular, the height h2 of the sidewall 25s of the rim 25 may be in a range of 5 to 10 μm. By adjusting the height of the sidewall 25s of the rim 25 to 10 μm or less, the distance between the bottom surface 23 of the pocket 27 and the substrate W is reduced, thereby accelerating the heat transfer.

Meanwhile, a height h3 from the rim 25 to the carrier upper surface 21u is almost similar to the thickness of the substrate W. The height h3 may be in a range of 200 to 400 μm, but the present invention is not limited thereto.

According to the embodiment, by reducing the curvature (1/R) of the bottom surface 23 of the pocket 27, the distance uniformity between the bottom surface of the GaN substrate W and the bottom surface 23 of the pocket 27 is increased. Accordingly, heat is evenly transferred over the entire area of the bottom surface of the GaN substrate W. As a result, epitaxial layers, including an n-type GaN-based semiconductor layer, an active layer, and a p-type GaN-based semiconductor layer, may be uniformly grown on the substrate W.

The wafer carrier 21 according to the embodiment of the present invention is used for supporting a GaN substrate (wafer) in a metal organic chemical vapor deposition (MOCVD) apparatus. When the GaN-based epitaxial layer is grown on the GaN substrate W, lattice mismatch is not great. Thus, wafer bowing rarely occurs. Therefore, the use of the wafer carrier 21 with the carrier pocket 27 according to the embodiment makes it possible to manufacture light emitting diodes having uniform characteristics within the single wafer.

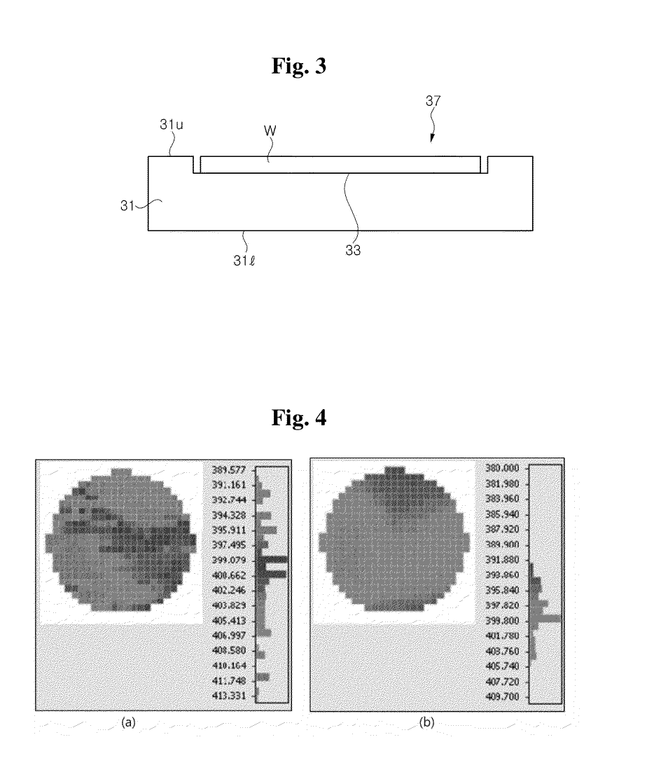

FIG. 3 is a partial cross-sectional view schematically illustrating a wafer carrier 30 according to another embodiment of the present invention.

Referring to FIG. 3, the wafer carrier 31 includes a carrier upper surface 31u, a carrier lower surface 31l, and a pocket 37, like in the wafer carrier 21 of FIG. 2. However, in this embodiment, the rim 25 of FIG. 2 is omitted, and the GaN substrate W is directly put on the bottom surface 33 of the pocket 37.

The bottom surface 33 may be substantially flat, but the height difference between the edge and the center of the bottom surface 33 may be 5 μm or less, like in the bottom surface 23 of FIG. 2.

While the epitaxial layer is grown in the CVD apparatus, wafer bowing does not substantially occur in the GaN substrate W. Therefore, by directly putting the substrate W on the substantially flat bottom surface 33 of the pocket 37, heat may be evenly transferred over the entire area of the wafer W.

FIGS. 4A and 4B are light distribution views illustrating wavelength distributions of light emitting diodes that are formed on a GaN substrate by using the conventional wafer carrier and the wafer carrier of the present invention. In the case of the wafer carrier of the present invention, the height difference h1 of the bottom surface of the pocket was almost zero, and the height h2 of the sidewall was about 4 μm. On the other hand, in the case of the conventional wafer carrier, the height difference h1 of the bottom surface of the pocket was about 10 μm, and the height h2 of the sidewall of the rim was about 45 μm.

Referring to FIGS. 4A and 4B, compared with the conventional wafer carrier, when the light emitting diodes are formed while putting the GaN substrate on the wafer carrier according to the embodiment of the present invention, it can be seen that uniformity of the light emission wavelengths of the light emitting diodes is improved. In particular, in the case of using the conventional wafer carrier, the average light emission wavelength of the light emitting diodes was 401.1 nm, and the standard deviation thereof was 6.1. On the other hand, in the case of using the wafer carrier according to the embodiment of the present invention, the average light emission wavelength of the light emitting diodes was 398.2 nm, and the standard deviation thereof was 2.84, which was rapidly reduced.

Moreover, in the case of using the wafer carrier according to the embodiment of the present invention, the average light emission strength was increased by 10% or more, as compared to the light emission strength when using the conventional wafer carrier. Also, the average full width at half maximum (FWHM) was reduced by about 20%.

According to the embodiments of the present invention, the wafer carrier may evenly transfer heat over the almost entire area of the GaN substrate, while the GaN layer and the active layer are grown on the GaN substrate used as the growth substrate. Moreover, by limiting the height of the sidewall of the rim, the distance between the GaN substrate and the bottom surface of the pocket is reduced. Therefore, the GaN substrate may be easily heated.

While the embodiments of the present invention have been described with reference to the specific embodiments, it will be apparent to those skilled in the art that various changes and modifications may be made without departing from the spirit and scope of the invention as defined in the following claims.

What is claimed is:

1. A wafer carrier for supporting a gallium nitride substrate in a chemical vapor deposition apparatus, the wafer carrier comprising:
a carrier lower surface;
a carrier upper surface; and
a pocket surrounded by the carrier upper surface,
wherein the pocket comprises:
a bottom surface; and
a rim arranged along an edge of the bottom surface and located under the carrier upper surface,
wherein the rim comprises a sidewall extending from the bottom surface, and an upper surface on which the gallium nitride substrate is arranged, and a height difference between an edge and a center of the bottom surface is 5 μm or less.

2. The wafer carrier according to claim 1, wherein a height of the sidewall of the rim is in a range of 5 to 10 μm.

3. The wafer carrier according to claim 1, wherein the carrier lower surface is substantially flat.

4. A wafer carrier for supporting a gallium nitride substrate in a chemical vapor deposition apparatus, the wafer carrier comprising:
a carrier lower surface;
a carrier upper surface; and
a pocket surrounded by the carrier upper surface,
wherein the pocket comprises a bottom surface on which the gallium nitride substrate is arranged.

5. The wafer carrier according to claim 4, wherein a height difference between an edge and a center of the bottom surface is less than 5 μm.

6. The wafer carrier according to claim 4, wherein the carrier lower surface is substantially flat.
